(19) United States
(12) Patent Application Publication
(10) Pub. No.: US 2011/0180133 A1
(43) Pub. Date: Jul. 28, 2011

(54) Enhanced Silicon-TCO Interface in Thin Film Silicon Solar Cells Using Nickel Nanowires

(75) Inventors: Steven VERHAVERBEKE, San Francisco, CA (US); Roman GOUK, San Jose, CA (US); Kurtis LESCHKIES, Santa Clara, CA (US)

(73) Assignee: Applied Materials, Inc., Santa Clara, CA (US)

(21) Appl. No.: 12/766,829

(22) Filed: Apr. 23, 2010

Related U.S. Application Data
(63) Continuation-in-part of application No. 12/553,300, filed on Sep. 3, 2009.
Application No. 12/553,300 is a continuation-in-part of application No. 12/419,178, filed on Apr. 6, 2009.
Application No. 12/419,178 is a continuation-in-part of application No. 12/258,263, filed on Oct. 24, 2008.

(51) Int. Cl. H01L 31/0224; H01L 31/18

(52) U.S. Cl. 136/256; 438/3; 118/620; 257/E31.126; 977/890; 977/948

(57) ABSTRACT

This invention provides an optically transparent electrically conductive layer with a desirable combination of low electrical sheet resistance and good optical transparency. The conductive layer comprises a multiplicity of magnetic nanostructures in a plane, aligned into a plurality of roughly parallel continuous conductive pathways, wherein the density of the magnetic nanostructures allows for substantial optical transparency of the conductive layer. The magnetic nanostructures may be nanoparticles, nanowires or compound nanowires. A method of forming the conductive layer on a substrate includes: depositing a multiplicity of magnetic nanostructures on the substrate and applying a magnetic field to form the nanostructures into a plurality of conductive pathways parallel to the surface of the substrate. The conductive layer may be used to provide an enhanced silicon to transparent conductive oxide (TCO) interface in thin film silicon solar cells.

### CROSS-REFERENCE TO RELATED APPLICATIONS

This application is a Continuation in Part of U.S. application Ser. No. 12/553,300, filed Sep. 3, 2009, which is a Continuation in Part of U.S. application Ser. No. 12/419,178, filed Apr. 6, 2009, which is a Continuation in Part of U.S. application Ser. No. 12/258,263, filed Oct. 24, 2008.

### FIELD OF THE INVENTION

The present invention relates generally to transparent conductive films in thin film solar cells and more specifically to transparent conductive films comprising magnetic nanostructures with work function matched to the solar cell material.

### BACKGROUND OF THE INVENTION

Optically transparent conductor layers are used in a variety of applications where a transparent conductor is either required or provides an advantage. Applications using transparent conductors include: liquid crystal displays, plasma displays, organic light emitting diodes, solar cells, etc. The transparent conducting oxides (TCOs), such as indium tin oxide and zinc oxide, are the most commonly used transparent conductor materials. However, TCO films represent a compromise between electrical conductivity and optical transparency—as carrier concentrations are increased to improve electrical conductivity, the optical transparency is reduced, and vice-a-versa. Furthermore, as the thickness of the TCO film is increased to improve electrical sheet resistance, the optical transparency is reduced. There is a need for optically transparent conductors with a more favorable compromise between electrical conductivity and optical transparency.

FIG. 1 shows a prior art solar cell device 100. Solar cell device 100 comprises a glass substrate 110, transparent conducting electrode (TCO) 120, active layer 130, and bottom electrode 140. Electron-hole pairs are generated in the active layer 130 by photons from light source 105 which travel through the glass substrate 110 and TCO 120 to reach the active layer 130. Individual cells, which generate a small voltage (typically 0.5-0.6 volts), are combined in series as shown in FIG. 1. The cells have a total width comprising the width of the active area of the cell, W_{A}, where electron-hole pairs contribute to the power generated, and the width of the dead area of the cell, W_{D}, where electron-hole pairs do not contribute. Current 150 flows through the device 100 as indicated. It is clear from the path followed by the current 150 that the sheet resistances of the TCO 120 and bottom electrode 140 are important in determining the resistive losses in the solar cell device 100. Further, these resistive losses will determine the maximum ratio of active cell area, indicated by W_{A}, to dead cell area, indicated by W_{D}. (The lower the resistive losses, the larger the ratio can be and the more efficient the device can be. See, for example, Brecl et al., Proc. 21^{st} European Photovoltaic Solar Energy Conference, 4-8 Sep. 2006, Dresden, Germany, pages 1662-1665.) Furthermore, it is clear that the efficiency of the solar cell device will be determined in part by the light transmission properties of the TCO 120. The sheet resistance of the TCO 120 is less for thicker films. Conversely, light transmission through the TCO 120 is greater for thinner films. Consequently, there is a compromise thickness for the TCO that will provide the best solar cell device performance. Again, there is a need for optically transparent conductors with a more favorable compromise between electrical conductivity and optical transparency.

Attempts to find a more favorable combination of optical transparency and electrical conductivity in a thin film optically transparent conductor have resulted in investigation of materials comprising two-dimensional networks of carbon nanotubes and silver nanowires. An example of the latter is shown in FIG. 2, which illustrates a thin film 210 comprising a random two-dimensional array of silver nanowires 220. For ease of illustration, FIG. 2 is not drawn to scale—it is intended only to illustrate the general nature of the arrangement of nanowires. Thin film 210 relies on the interconnection of individual nanowires 220 for electrical conductivity. The optical transparency comes from the low density of metal in the thin film 210. As can be seen in FIG. 2, the current pathways through the thin film 210 will be very convoluted and do not make efficient use of the silver nanowires 220. Furthermore, since the nanowires 220 are not being used efficiently to provide electrical conduction in the thin film 210, the film 210 will have a less than optimum optical transparency. Clearly, the combination of electrical conductivity and optical transparency that is available from thin films comprising nanowires has yet to be fully optimized.

### SUMMARY OF THE INVENTION

Embodiments of this invention provide an optically transparent conductive layer with a desirable combination of low electrical sheet resistance and good optical transparency. The transparent conductive layer is comprised of magnetic nanowires and/or magnetic nanoparticles which are (1) at a low enough density to provide good optical transparency, and (2) arranged to optimize electrical conductivity. The properties of the transparent conductive layer may be optimized to provide good optical transmission, greater than 90% over the wavelength range of 250 nm to 1.1 microns, and low sheet resistance, less than 20 Ohm/square at room temperature. The concepts and methods of this invention allow for integration of the transparent conductive layer into devices such as solar cells, displays and light emitting diodes.

According to aspects of this invention, a conductive layer comprises a multiplicity of magnetic nanowires in a plane, the nanowires being aligned roughly (1) parallel to each other and (2) with the long axes of the nanowires in the plane of the layer, the nanowires further being configured to provide a plurality of continuous conductive pathways, and wherein the density of the multiplicity of magnetic nanowires allows for substantial optical transparency of the conductive layer. Furthermore, the conductive layer may include an optically transparent continuous conductive film, wherein the multiplicity of magnetic nanowires are electrically connected to the continuous conductive film; the continuous conductive film may be either coating the multiplicity of magnetic nanowires or the multiplicity of magnetic nanowires may be on the surface of the continuous conductive film.

According to further aspects of this invention, a method of forming a conductive layer on a substrate is provided, where the conductive layer is substantially optically transparent and includes magnetic conductive nanowires. The method comprises: depositing a multiplicity of magnetic conductive nanowires on the substrate; and applying a magnetic field to form the nanowires into a plurality of conductive pathways parallel to the surface of the substrate. The depositing step may include spraying a liquid suspension of the nanowires onto the surface of the substrate. After the depositing step, the nanowires may be coated with a conductive metal, for example by an electroless plating process.

According to yet further aspects of this invention, the magnetic conductive nanowires may be compound magnetic nanowires. The compound magnetic nanowires may comprise: a non-magnetic conductive center; and a magnetic coating. For example, the non-magnetic center may be silver and the magnetic coating may be cobalt or nickel. Furthermore, the compound magnetic nanowires may comprise: a first cylindrical part comprising a magnetic material; and a second cylindrical part attached to the first cylindrical part, the first and second cylindrical parts being aligned coaxially, the second cylindrical part comprising a carbon nanotube.

According to another aspect of this invention, the method of forming a conductive layer on a substrate may further include providing a multiplicity of compound magnetic nanowires where the providing may include: forming silver nanowires in solution; and coating the silver nanowires with a magnetic metal. Furthermore, the providing of compound magnetic nanowires may include: forming a magnetic metal nanowire; and growing a carbon nanotube on the end of the magnetic metal nanowire.

According to aspects of this invention, a conductive layer comprises a multiplicity of magnetic nanoparticles in a plane, the nanoparticles being aligned in strings, the strings being roughly parallel to each other and configured to provide a plurality of continuous conductive pathways, and wherein the density of the multiplicity of magnetic nanoparticles allows for substantial optical transparency of the conductive layer. Furthermore, the conductive layer may include an optically transparent continuous conductive film, wherein the multiplicity of magnetic nanoparticles are electrically connected to the continuous conductive film; the continuous conductive film may be either coating the multiplicity of magnetic nanoparticles or the multiplicity of magnetic nanoparticles may be on the surface of the continuous conductive film.

According to further aspects of this invention, a method of forming a conductive layer on a substrate is provided, where the conductive layer is substantially optically transparent and includes magnetic conductive nanoparticles. The method comprises: depositing a multiplicity of magnetic conductive nanoparticles on the substrate; and applying a magnetic field to form the nanoparticles into a plurality of conductive pathways parallel to the surface of the substrate. The depositing may include spraying a liquid suspension of the nanoparticles onto the surface of the substrate. After the depositing step, the nanoparticles may be coated with a conductive metal, for example by an electroless plating process. Furthermore, the applying may include fusing the nanoparticles together in continuous conductive pathways.

Furthermore, the conductive layer formed using the methods of the present invention may be used to provide an enhanced semiconductor material to transparent conductive oxide (TCO) interface in thin film solar cells. Nickel and cobalt nanowires/nanoparticles are used with p-type silicon due to their work functions which match that of the p-type silicon and result in improved solar cell performance.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a perspective view of a prior art solar cell;

FIG. 2 is a top view of a prior art conductive film comprising nanowires;

FIG. 3 is a top view of a conductive coating comprising magnetic nanowires, according to some embodiments of the invention;

FIG. 4 is a view of a vertically oriented substrate coated with magnetic nanowires prior to applying an external magnetic field, according to some embodiments of the invention;

FIG. 5 is a view of the substrate of FIG. 4 after applying an external magnetic field, according to some embodiments of the invention;

FIG. 6 is a perspective view of a compound magnetic nanowire, according to some embodiments of the invention;

FIG. 7 is a perspective view of a substrate with a transparent conductive layer comprising a conductive film and a layer of oriented magnetic nanowires, according to some embodiments of the invention;

FIG. 8 is a top view of a conductive coating comprising magnetic nanoparticles, according to some embodiments of the invention;

FIGS. 9A-9D are a representation of a process for fabricating cobalt-CNT wires, according to some embodiments of the invention;

FIG. 10 shows a dark band diagram for a solar cell with a typical TCO;

FIG. 11 shows a dark band diagram for a solar cell with a Ni nanowire transparent conductive film, according to some embodiments of the invention;

FIG. 12 is a cross sectional representation of a solar cell with a nickel nanowire transparent conductive film, according to some embodiments of the invention; and

FIG. 13 is a diagrammatic representation of a first process apparatus for fabricating thin film solar cells, according to some embodiments of the invention; and

FIG. 14 is a diagrammatic representation of a second process apparatus for fabricating thin film solar cells, according to some embodiments of the invention.

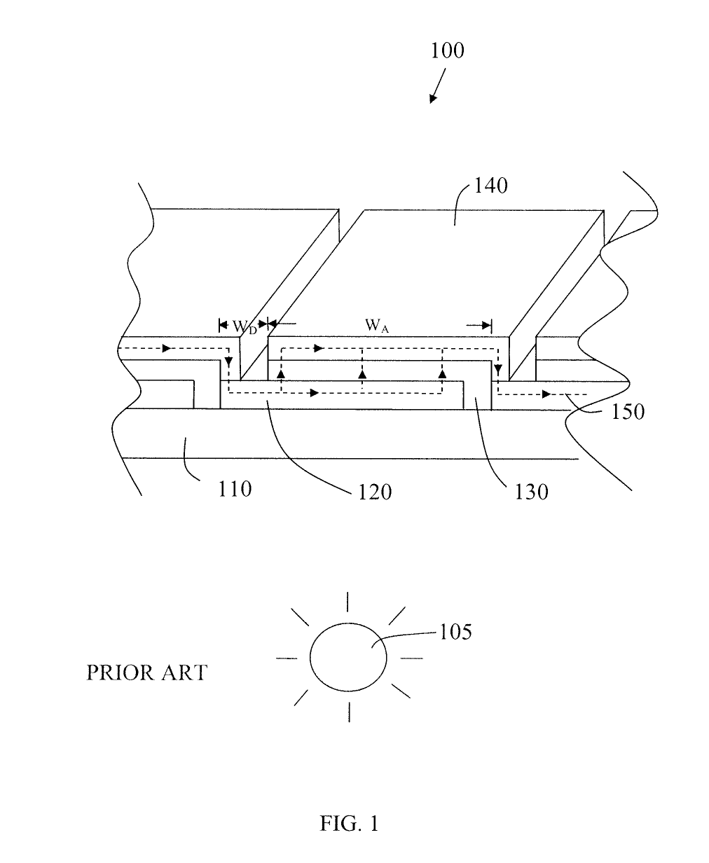

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In general, the present invention contemplates a transparent conductive layer comprising magnetic nanowires and/or magnetic nanoparticles with an optimal combination of both electrical conductivity and optical transparency. The magnetic nanowires and/or magnetic nanoparticles are aligned in a magnetic field to form continuous conductive pathways in the plane of the conductive layer. The transparent conductive layer has a combination of substantial optical transparency and substantial electrical conductivity. For example, some embodiments of the transparent conductive layer may have optical transmission greater than 70% over the wavelength range of 250 nm through 510 nm, and sheet resistance less than 50 Ohm/square. A sub-set of these embodiments of the transparent conductive layer may have optical transmission of greater than 80% over the wavelength range of 250 nm through 1.1 microns, and sheet resistance less than 20 Ohm/square at room temperature. A further sub-set of these embodiments of the transparent conductive layer may have optical transmission greater than 90% over the wavelength range of 250 nm to 1.1 microns, and sheet resistance less than 20 Ohm/square at room temperature.

Furthermore, the conductive layer formed using the methods of the present invention may be used to provide an enhanced semiconductor material to transparent conductive oxide (TCO) interface in thin film solar cells. For example, nickel and cobalt nanowires/nanoparticles are used with p-type silicon due to their work functions which match that of the p-type silicon and result in improved solar cell performance.

Magnetic nanowires may be fabricated by an electrochemical process—either electroless deposition or electrodeposition—in a template. For example, nickel or cobalt metal may be deposited in the pores of porous anodized alumina. See Srivastava et al., Metallurgical and Materials Transactions A, 38A, 717 (2007); Bentley et al., J. Chem. Education, 82(5), 765 (2005); Yoon et al., Bull. Korean Chem. Soc., 23(11), 1519 (2002). The magnetic nanowires are in the general range of 5 to 300 nm in diameter, preferably 10-100 nm in diameter, and most preferably 40 nm in diameter. The magnetic nanowires may have an aspect ratio—length to diameter—in the range of 5:1 to 100:1, and preferably 10:1. The length to diameter ratio is primarily limited by the fabrication method of the nanowires. If a template is used to fabricate the nanowires, then the template is limiting the length to diameter ratio. The nanowires comprise magnetic material, such as nickel metal, as discussed in more detail below. Furthermore, processes for forming magnetic nanowires without using a template are described below with reference to FIG. 6.

Magnetic nanoparticles may be fabricated by a solution method. For example, nickel/cobalt metal may be precipitated from a solution. The magnetic nanoparticles are in the general range of 5 to 300 nm in diameter, preferably 10-100 nm in diameter, and most preferably 40 nm in diameter. The magnetic nanoparticles are generally spherical; however, other shapes may be utilized, including dendritic forms. The nanoparticles comprise magnetic material, such as nickel and cobalt metals. See Srivastava et al.

First, some embodiments of the present invention including nanowires will be described with reference to FIGS. 3-7.

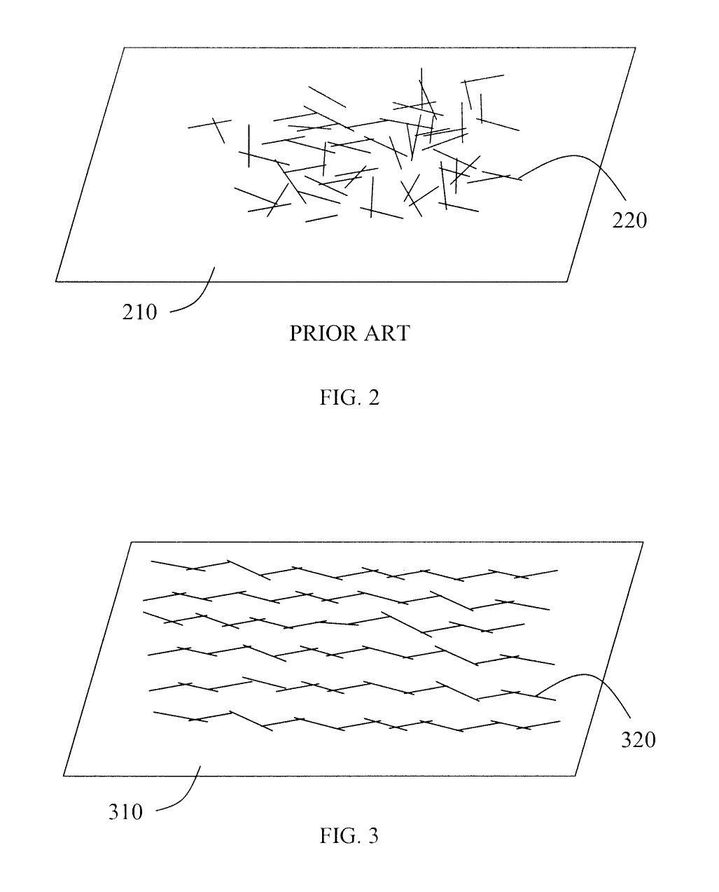

FIG. 3 shows a two-dimensional network of metallic nanowires according to some embodiments of the invention. For ease of illustration, FIG. 3 is not drawn to scale—it is intended only to illustrate the general nature of the arrangement of nanowires. The network of metallic nanowires in FIG. 3 provides a more favorable combination of optical transparency and electrical conductivity in a thin film optically transparent conductor than is available in the prior art shown in FIG. 2. FIG. 3 illustrates a thin film 310 comprising an ordered two-dimensional array of metallic nanowires 320. The thin film 310 may consist of the metallic nanowires 320 alone, distributed on the surface of a substrate. However, the thin film 310 may also comprise other materials, such as a continuous substantially optically transparent conductive film, as described below. The nanowires 320 are aligned roughly: (1) parallel to each other; and (2) with their long axes in the plane of the thin film 310. Thin film 310 relies on the interconnection of individual nanowires 320 for electrical conductivity—the nanowires 320 are configured to provide a plurality of continuous conductive pathways. (Six such pathways are illustrated in FIG. 3). The optical transparency comes from the low density of metal in the thin film 310. More specifically, for solar cell applications, substantial optical transparency is required for wavelengths below approximately 1.1 microns. (Photons with wavelengths below approximately 1.1 microns may produce electron-hole pairs in the active layer of a typical solar cell.) As can be seen in FIG. 3, the current pathways through the thin film 310 make optimum use of the nanowires 320. The combination of electrical conductivity and optical transparency provided by the present invention provides an advantage for applications such as solar cells.

Referring again to FIG. 3, a desirable spacing between adjacent continuous conductive pathways is in the range of 50 nm to 1 μm. This range provides a desirable combination of electrical conductivity and optical transparency for a thin film optically transparent conductor comprising nanowires.

The nanowires 320 in FIG. 3 are magnetic, allowing for their alignment using a magnetic field. The nanowires 320 comprise magnetic material, such as magnetic metals, magnetic alloys and magnetic compounds. In preferred embodiments the nanowires 320 comprise transition metals such as nickel, cobalt and iron.

Nanowires 320 can comprise a single magnetic metal or a combination of metals chosen for their magnetic and electrical conductive properties. FIG. 6 shows a compound nanowire 600. The nanowire 600 has a core 620 of a first metal and a coating 610 of a second metal. The core 620 may be a magnetic metal and the coating 610 may be a metal chosen for its high electrical conductivity. For example, the coating 610 may comprise a metal such as copper, silver, gold, palladium or platinum, or a suitable alloy. Alternatively, the coating 610 may be a magnetic metal and the core 620 may be a metal chosen for its high electrical conductivity.

Furthermore, compound nanowires can be fabricated wherein the compound nanowire 600 comprises a core 620 chosen for ease of fabrication and a coating 610 which is magnetic. For example, the core 620 can be a silver nanowire precipitated out of solution, and the coating 610 can be formed by electroless deposition of nickel or cobalt metal onto the silver nanowires. The silver nanowires also provide excellent electrical conductivity. The silver nanowires can be precipitated out of solution using a method such as that described by Kylee Korte, “Rapid Synthesis of Silver Nanowires,” 2007 National Nanotechnology Infrastructure Network Research Experience for Undergraduates Program Research Accomplishments, 28-29, available at http://www.nnin.org/doc/2007NNINreuRA.pdf last visited Jul. 9, 2009. The method described by Korte involves precipitation of silver nanowires from a solution including silver nitrate, poly(vinylpyrrolidone) (PVP), ethylene glycol and copper(II) chloride. This method may provide an inexpensive process, compared to electroplating of wires in an anodized alumina template, for forming silver nanowires with good control over nanowire dimensions. Silver nanowires are also commercially available. The silver nanowires can then be plated with nickel or cobalt metal using commercially available electroless plating solutions. Nickel coated silver wires may be fabricated with a diameter chosen over a wide range, although a 20-40 nanometer silver core diameter, with a 5-50 nanometer nickel coating is suitable for making a TCO replacement according to some embodiments of the present invention.

A method according to the present invention for forming a conductive layer such as the thin film 310 shown in FIG. 3 includes the following steps. First, a substrate is provided. In the case of a solar device, the substrate may be a glass substrate. Second, magnetic, electrically conductive nanowires are deposited on the surface of the substrate. The deposition step may conveniently comprise spraying a liquid suspension of nanowires onto the surface of the substrate. Third, a magnetic field, with field lines parallel to the surface of the substrate, is applied, preferably while the substrate is still wet. The magnetic field forms the nanowires into a plurality of conductive pathways parallel to the magnetic field lines. The alignment of the nanowires to the magnetic field lines may be assisted by orienting the substrate such that the substrate surface is in a vertical plane. Furthermore, after the deposition step the nanowires may be coated with a conductive metal such as gold or silver, using techniques such as electroless plating. For example, nickel or cobalt nanowires may be immersion coated with silver or gold by a spray process such as electroless nickel immersion gold (ENIG), currently used to make solder bump pads with a thin layer of gold on a nickel pad. This immersion coating process may assist in fixing the nanowires in place in their aligned configuration.

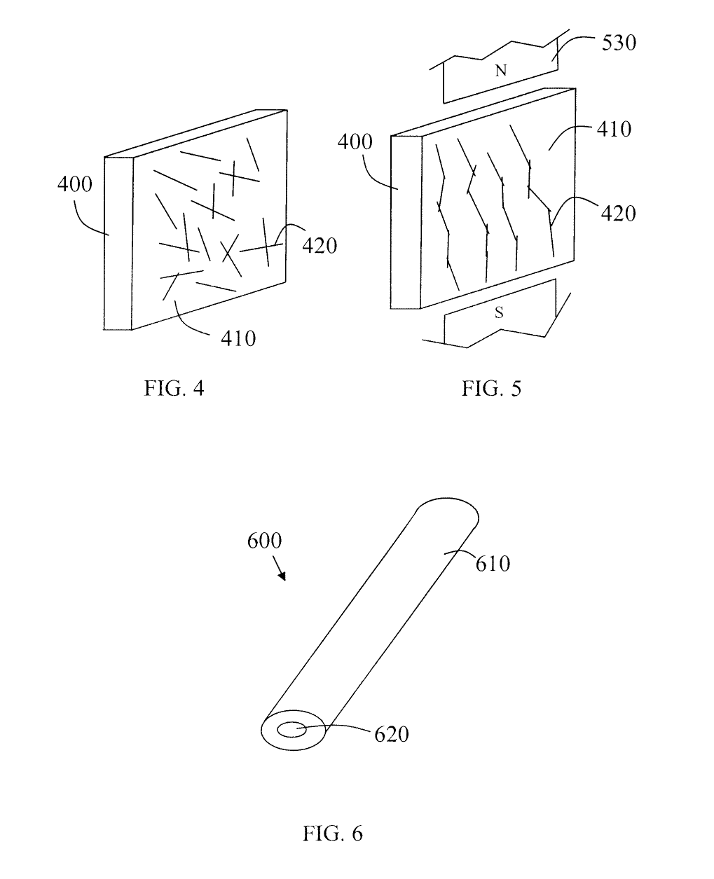

FIGS. 4 & 5 illustrate the effect of applying a magnetic field to magnetic nanowires 420 deposited on the surface 410 of a substrate 400. For ease of illustration, FIGS. 4 & 5 are not drawn to scale—it is intended only to illustrate the general nature of the arrangement of nanowires. In FIG. 4, the nanowires 420 are shown in their as-deposited arrangement on the surface 410—this arrangement is a substantially random two-dimensional arrangement. In preferred embodiments of the method, the substrate 400 is oriented with the surface 410 in a vertical plane. A magnetic field may be applied by magnet(s) 530, as illustrated in FIG. 5. The magnetic field may also be applied using a coil. There are many ways in which a magnetic field may be applied, as will be apparent to those skilled in the art. The requirement for the magnetic field is that the magnetic field lines run roughly parallel to the surface 410. (In the preferred embodiment shown in FIG. 5, where the surface of the substrate is oriented in a vertical plane, the source of the magnetic field is configured so that the magnetic field lines also run vertically.) As shown in FIG. 5, the nanowires 420 are roughly aligned to the magnetic field. Furthermore, the magnetic nanowires 420 are shown to arrange themselves to form continuous lines. The arrangement of magnetic nanowires 420 shown in FIG. 5 is favored since the formation of continuous lines of magnetic nanowires is a low energy state for the magnetic circuit. Furthermore, having the substrate in a vertical orientation is expected to facilitate the movement of nanowires 420, as the nanowires 420 re-orient themselves into a lower energy state.

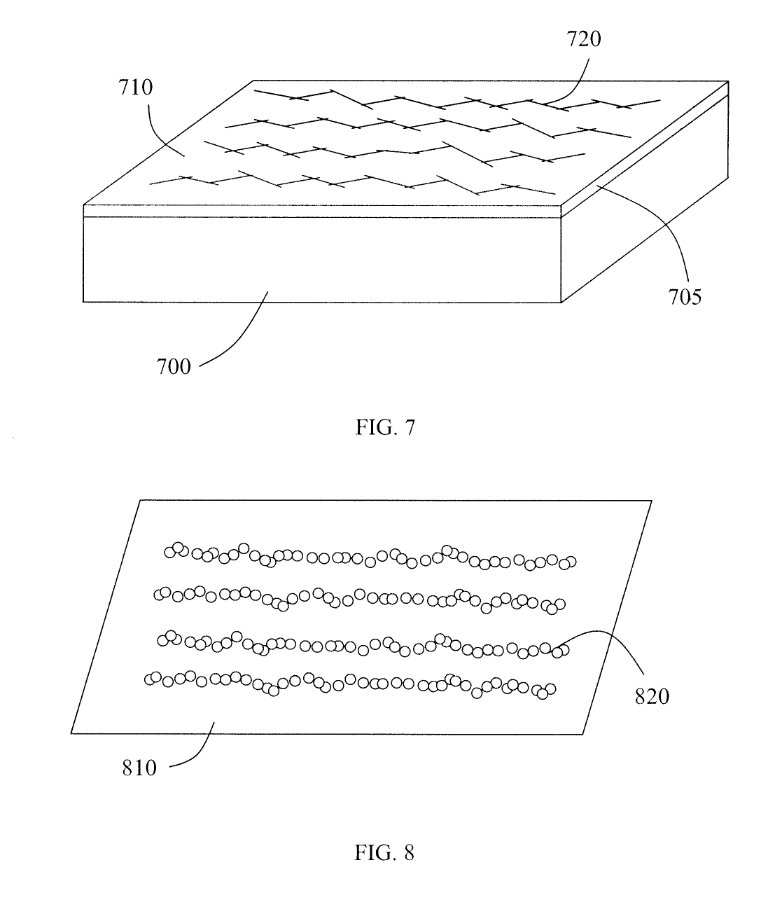

FIG. 7 illustrates a substrate 700 with a thin film 705 and oriented nanowires 720 on the film surface 710. For ease of illustration, FIG. 7 is not drawn to scale—it is intended only to illustrate the general nature of the arrangement of nanowires and the thin film on the substrate. The thin film 705 is a continuous transparent film which is substantially optically transparent and electrically conductive. The thin film 705 may be a TCO such as indium tin oxide or zinc oxide. The thin film 705 is deposited on the substrate 700 using deposition methods well known to those skilled in the art, including sputter deposition. The oriented nanowires 720 are formed into a plurality of continuous conductive pathways, as described above. Furthermore, the magnetic nanowires 720 are electrically connected to the transparent thin film 705. To help ensure good electrical contact between the nanowires 720 and the thin film 705, oxide may be removed from the nanowires prior to deposition on the thin film using an acid dip or equivalent process.

The integration of the aligned magnetic nanowires 720 and the electrically conductive, optically transparent thin film 705 provides an electrically conductive, optically transparent layer which, in preferred embodiments, has a long range electrical conductivity determined primarily by the properties of the aligned magnetic nanowires 720 and a short range electrical conductivity (on the length scale of the separation between adjacent continuous conductive pathways) determined primarily by the properties of the thin film 705. This integrated layer allows for a thin film 705 with a thickness optimized primarily for optical transparency, since the electrical conductivity is provided primarily by the aligned magnetic nanowires 720. The thin film 705 and the layer of aligned nanowires 720 are effectively two dimensional structures; therefore, the electrical conductivity of these structures may most conveniently be discussed in terms of sheet resistance. If a combination of magnetic nanowires and a thin electrically continuous conductive film is used, then it is not absolutely necessary for the magnetic nanowires to be all connected into a continuous string. Indeed, short interruptions in the string of nanowires may then be accommodated by a short current path through the electrically conductive film.

In an alternative embodiment (not shown), the aligned nanowires, as shown in FIG. 3, are coated with an electrically conductive, optically transparent layer, such as a TCO. This integrated structure is similar to the structure of FIG. 7, except the nanowires are coated by TCO rather than sitting on TCO. The TCO may be sputter deposited directly on top of the aligned nanowires and will be effective in fixing the nanowires in place in the desired configuration. The TCO may be indium tin oxide or zinc oxide. The TCO may also be deposited on the nanowire coated substrate using other deposition methods well known to those skilled in the art.

Some embodiments of the present invention which include nanoparticles will now be described, with reference to FIG. 8.

FIG. 8 shows a two-dimensional network of metallic nanoparticles according to some embodiments of the invention. For ease of illustration, FIG. 8 is not drawn to scale—it is intended only to illustrate the general nature of the arrangement of nanoparticles. The network of metallic nanoparticles in FIG. 8 provides a more favorable combination of optical transparency and electrical conductivity in a thin film optically transparent conductor than is available in the prior art shown in FIG. 2. FIG. 8 illustrates a thin film 810 comprising an ordered two-dimensional array of metallic nanoparticles 820. The thin film 810 may consist of the metallic nanoparticles 820 alone, distributed on the surface of a substrate. However, the thin film 810 may also comprise other materials, such as a continuous substantially optically transparent conductive film, as described above with reference to FIG. 7. The nanoparticles 820 are aligned in strings, the strings being roughly parallel to each other. Thin film 810 relies on the interconnection of individual nanoparticles 820 for electrical conductivity—the nanoparticles 820 are configured to provide a plurality of continuous conductive pathways. (Four such pathways are illustrated in FIG. 8). The optical transparency comes from the low density of metal in the thin film 810. More specifically, for solar cell applications, substantial optical transparency is required for wavelengths below approximately 1.1 microns. (Photons with wavelengths below approximately 1.1 microns can produce electron-hole pairs in the active layer of a typical solar cell.) As can be seen in FIG. 8, the current pathways through the thin film 810 make optimum use of the nanoparticles 820. The combination of electrical conductivity and optical transparency provided by the present invention provides an advantage for applications such as solar cells.

Referring again to FIG. 8, a desirable spacing between adjacent continuous conductive pathways is in the range of 50 nm to 1 μm. This range provides a desirable combination of electrical conductivity and optical transparency for a thin film optically transparent conductor comprising nanoparticles.

The nanoparticles 820 in FIG. 8 are magnetic, allowing for their alignment using a magnetic field. The nanoparticles 820 comprise magnetic material, such as magnetic metals, magnetic alloys and magnetic compounds. In preferred embodiments the nanoparticles 820 comprise transition metals such as nickel and cobalt.

Nanoparticles 820 can comprise a single magnetic metal or a combination of metals chosen for their magnetic and electrical conductive properties. For example, nanoparticles may have a core of a first metal and a coating of a second metal. The core may be a magnetic metal and the coating may be a metal chosen for its high electrical conductivity, or vice-versa. For example, the coating may comprise a metal such as copper, silver, gold, palladium or platinum, or a suitable alloy, chosen for electrical conductivity.

A method according to the present invention for forming a conductive layer such as the thin film 810 shown in FIG. 8 may be as follows. First, a substrate is provided. In the case of a solar device, the substrate may be a glass substrate. Second, magnetic, electrically conductive nanoparticles are deposited on the surface of the substrate. The deposition step may conveniently comprise spraying a liquid suspension of nanoparticles onto the surface of the substrate. Third, a magnetic field, with field lines parallel to the surface of the substrate, is applied, preferably while the substrate is still wet. The magnetic field forms the nanoparticles into a plurality of conductive pathways parallel to the magnetic field lines. The arrangement of magnetic nanoparticles into continuous lines is a low energy state for the magnetic circuit. Furthermore, having the substrate in a vertical orientation is expected to facilitate the movement of nanoparticles 820, as the nanoparticles 820 re-orient themselves into a lower energy state.

After the deposition of the nanoparticles, the substrate may be subjected to a hydrogen plasma to remove oxides from the surface of the particles. Furthermore, the substrate may be heated in a reducing atmosphere, so as to fuse together the nanoparticles. The heating may also improve the bonding of the nanoparticles to the substrate.

Furthermore, after the deposition, the nanoparticles may be coated with a conductive metal such as gold or silver, using techniques such as electroless plating. For example, nickel or cobalt nanoparticles may be immersion coated with silver or gold by a spray process such as electroless nickel immersion gold (ENIG). This immersion coating process may assist in fixing the nanoparticles in place in their aligned configuration.

In light of the description provided above with reference to FIG. 8, those skilled in the art will appreciate how nanoparticles may be used in place of nanowires in the embodiments described above with reference to FIGS. 3-7.

Carbon nanotubes (CNTs) have physical properties that make them attractive for use in a TCO layer replacement—for example an armchair (n,n) type CNT can carry approximately 10³ times the current density of a copper wire of the same diameter. However, CNTs are not magnetic and therefore cannot be aligned in a magnetic field. In a further embodiment of the present invention, CNTs are formed into compound magnetic nanowires comprising a magnetic metal portion. These compound magnetic nanowires may be used in place of, or in combination with, the magnetic nanowires in some of the embodiments of the invention described above to form TCO replacement layers.

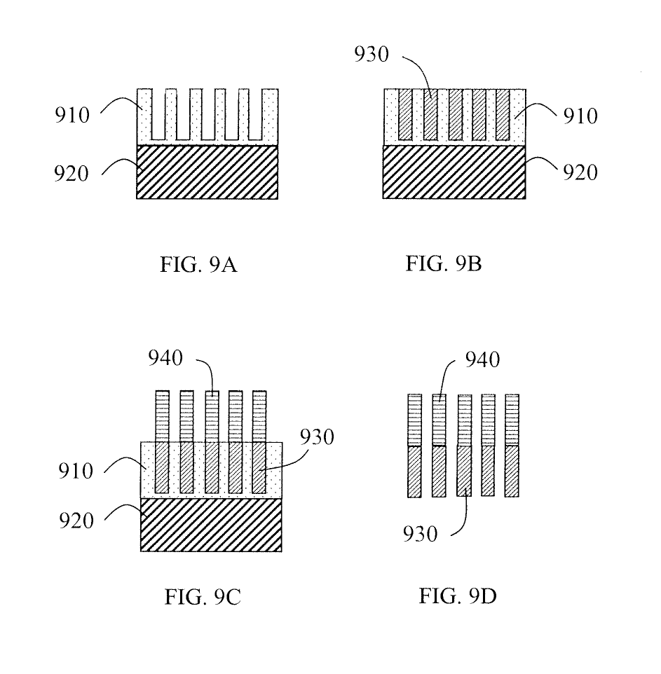

FIGS. 9A-9D illustrate a process for forming compound magnetic nanowires comprising a magnetic metal portion and a CNT portion. FIG. 9A shows a layer of porous anodized alumina 910 formed on an aluminum substrate 920. The pores may be in the range of 10-50 nanometers in diameter, which also specifies the diameter of the plated nanowires and the CNTs. FIG. 9B shows a magnetic metal, for example cobalt or nickel, electroplated into the porous anodized alumina 910 to form nanowires 930. (The pores in FIG. 9B are shown completely filled by plated nanowires 930; however, the plating does not need to completely fill the pores.) The length of the cobalt or nickel nanowires need only be several microns long. FIG. 9C shows CNTs 940 formed on top of the nanowires 930. The growth of the CNTs 940 is catalyzed by the nanowires 930. The CNTs are formed as is well known to those skilled in the art, by a process such as chemical vapor deposition (CVD), laser ablation or carbon-arc. FIG. 9D shows the compound nanowires released from the anodized alumina template—the release is done by dissolving the alumina in a base such as sodium hydroxide. Methods for formation of porous anodized alumina and for electroplating metal into the pores are well known in the art; for example, see: Bentley et al., J. Chem. Education, 82(5), 765 (2005); and Yoon et al., Bull. Korean Chem. Soc., 23(11), 1519 (2002).

Although embodiments of the present invention have been described with reference to the use of either nanoparticles or nanowires, the present invention may be implemented with a combination of nanoparticles and nanowires or with any other equivalent nano-sized magnetic conductive objects.

Enhanced Silicon-Transparent Conductor Interface

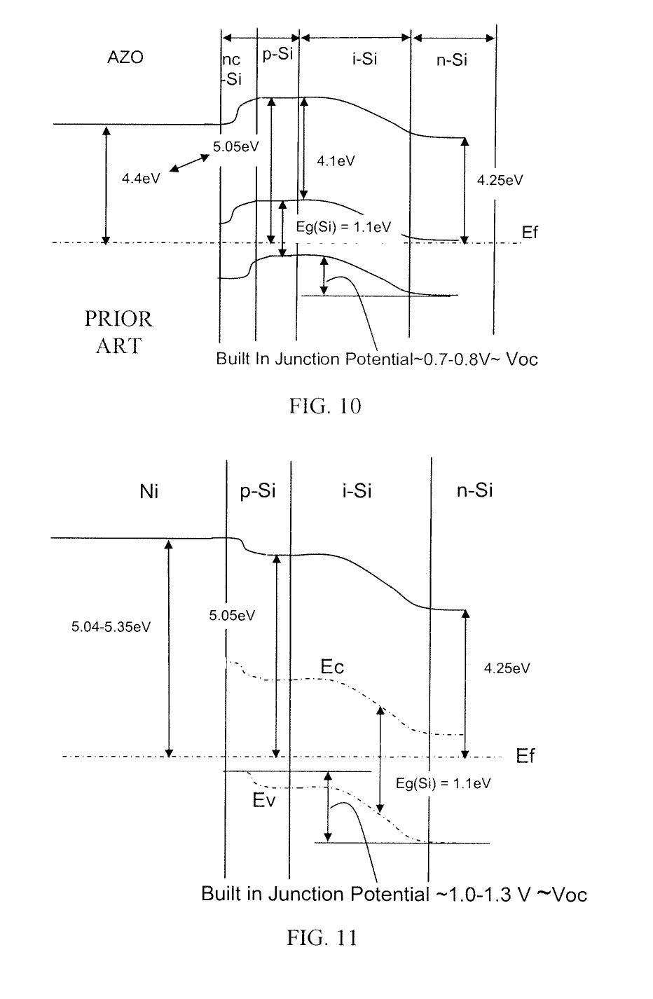

Typical transparent conductors, such as zinc oxide and tin oxide materials, in thin film silicon solar cells have poor work function match to the p-Si layer. The prior art solution to this problem is to have a highly doped “shield” layer at the interface between the transparent conductor and the p-Si layer. FIG. 10 shows a dark band diagram of a p-i-n thin film solar cell attached to an aluminum doped zinc oxide (AZO) transparent conductor. To accommodate the work function mismatch between the AZO and the p-Si there is a highly doped silicon layer inserted between the AZO and the p-Si to make ohmic contact with the transparent conductor and to shield the silicon active layers from the transparent conductor's work function, thus minimizing photovoltage loss. The highly doped silicon layer may be a nanocrystalline silicon (nc-Si) layer or a microcrystalline layer, for example. The highly doped silicon layer may improve the open circuit voltage (V_{oc}) as well as the series resistance and fill factor of the solar cell. However, the highly doped silicon “shield” layer, which may need to be thick to be effective, absorbs a significant amount of light in the UV spectrum, thus reducing the solar cell efficiency. A solution to this problem is to use a transparent conducting film which has a work function that matches the work function of the p-Si.

According to some embodiments of the present invention, a transparent conductive layer comprising magnetic nanostructures with a work function matching p-Si is used in place of or in addition to the typical TCO film. The nanostructures may be nanowires or nanoparticles, as described above. The nanostructures include a material, such as nickel, which has a work function close to or higher than that of the p-Si. FIG. 11 shows a dark band diagram of a p-i-n thin film solar cell attached to a transparent conductor film including nickel nanostructures. An improvement in the Voc and efficiency of the silicon solar cell with the band structure of FIG. 11 is expected over the prior art. Other than Ni, another magnetic metal that has a favorable work function for matching p-type silicon is cobalt. Furthermore, iron may not have as good a work function match to p-type silicon as either Ni or Co, but it is a better work function match than AZO and thus is an improvement over AZO.

The concepts of the invention may also be applied to matching the work function of n-type silicon. A lower work function, around 4.25-4.35 eV, is required for matching n-type silicon. Suitable metals include Al, Ti, In, Ca and Mg; these metals are not magnetic, but may be coated onto a magnetic core, as described above with reference to FIG. 6 or combined with a magnetic portion in a compound nanowire, as described above with reference to FIGS. 9A-9D.

Further to the improved work function matching, some embodiments of the invention also provide improved adhesion of nanowires to p-type silicon. For example, nickel nanowires exhibit better adhesion to p-type silicon than silver nanowires. Consequently, Ni coated Ag nanowires may be used to advantage for improved adhesion and work function matching, while maintaining the high conductivity of the Ag. The Ag nanowires may be coated with Ni using an electroless plating process, for example. The Ag nanowires may first undergo a galvanic surface replacement process with a noble metal, such as Pd, to help facilitate the Ni coating. The Ag/Pd nanowires may then be placed into a Ni-containing plating solution, where the Ni can be deposited via electroless reduction onto the nanowire surface.

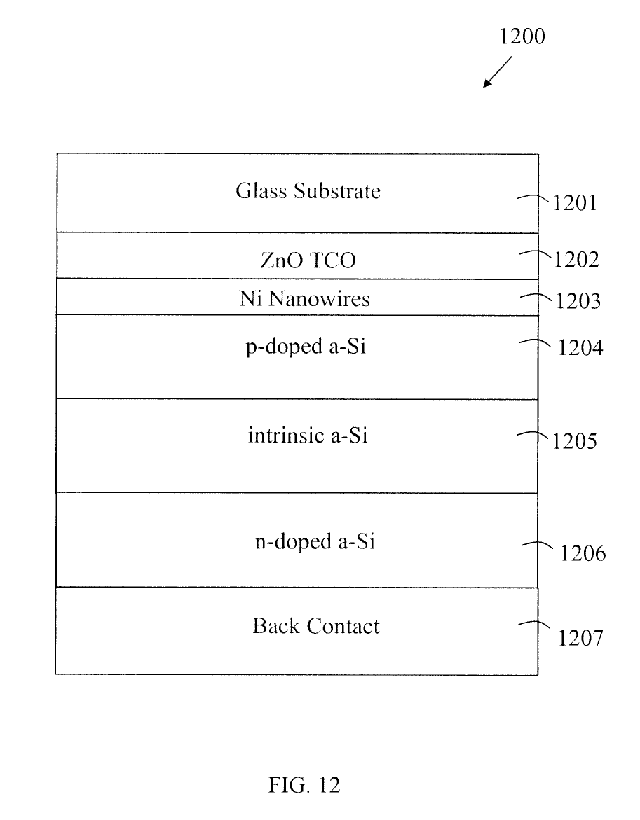

FIG. 12 shows an example of a solar cell according to some embodiments of the present invention in which an electrically conductive optically transparent film of nickel nanowires are used to match the work function of a p-doped amorphous silicon layer. The solar cell 1200 comprises a glass substrate 1201, a ZnO TCO layer 1202, an electrically conductive optically transparent film of Ni nanowires 1203 formed as described above, p-doped amorphous silicon (a-Si) layer 1204, intrinsic a-Si layer 1205, n-doped amorphous silicon layers 1206 and a back contact 1207. The back contact 1207 may comprise a TCO layer and/or a metal layer. The back contact 1207 may also comprise compound nanowires consisting of a low workfunction metal, a TCO layer and/or a metal layer. Although an amorphous silicon solar stack (layers 1204, 1205 and 1206) is shown on FIG. 12, the solar stack may also be formed of microcrystalline silicon, single crystal silicon, or other materials such as SiGe, CIGS, GaAs, InP and CdTe.

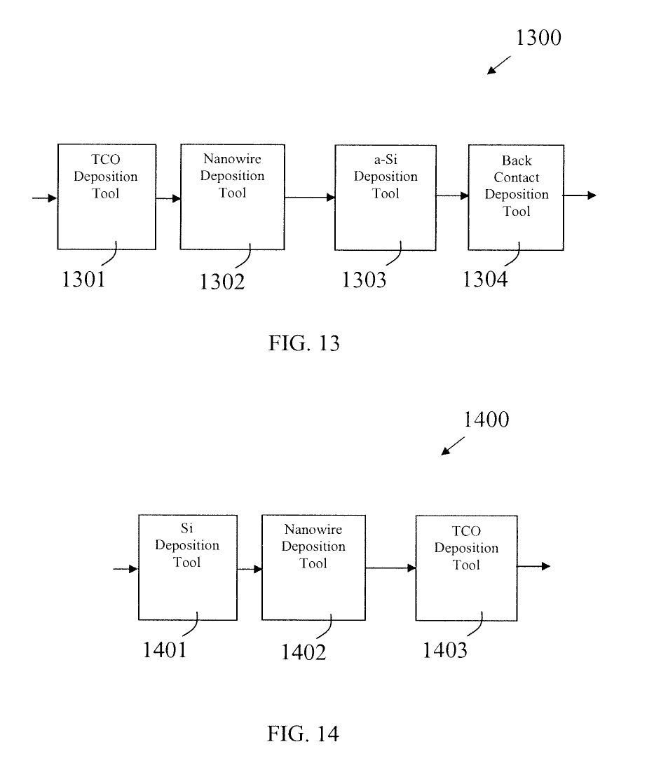

FIG. 13 shows an example of an apparatus for fabricating solar cells with an enhanced silicon-transparent conductor interface, such as the solar cell of FIG. 12, according to the methods of this invention. The apparatus of FIG. 13 comprises four systems. The first system 1301 deposits a TCO layer on a glass substrate. An example of such a system is a sputter deposition tool. The second system 1302 deposits Ni nanowires on the surface of the TCO, following the method and tools described above with reference to FIG. 5. The third system 1303 deposits an amorphous silicon stack—p, i and n layers—on the TCO layer coated with Ni nanowires. An example of such a system is a PECVD tool. Note that the reducing atmosphere used in PECVD deposition helps to remove any oxide on the surface of the Ni nanowires, ensuring good electrical contact between the nanowires and the p-type a-Si. The fourth system 1304 deposits the back contact on the amorphous silicon stack. The back contact may comprise low work function compound nanowires, a TCO layer and/or a metal layer. An example of a system for depositing the TCO and metal layers is a sputter tool or an electron beam evaporation tool.

System 1301 is optional, since the nanowires may be deposited directly onto a glass substrate to form a transparent conductive electrode (TCE). Furthermore, glass substrates may be provided with a TCO already present on the surface using an in-line pyrolytic glass coating process.

Furthermore, after the nanowires are aligned on the surface of the TCO, the nanowires may be annealed and/or pressed using a compressive force to further improve the electrical connection between contacting nanowires and/or assist in fixing the nanowires in place in their aligned configuration. The nanowires may be annealed at temperatures ranging from 100-250° C. to facilitate fusing together or interconnecting individual nanowires in their aligned configuration. Additionally, the nanowires in their aligned configuration can be pressed or fused together using a hydraulic press to supply compressive force in the range of 1-20 tons prior to deposition of the silicon solar stack. To reduce contact resistance between nanowires, the nanowires may be subjected to one or more of etching, annealing and/or pressing. The etching removes surface oxide. Tools for annealing, pressing and etching may be included in system 1302.

FIG. 14 shows an example of another apparatus for fabricating solar cells with an enhanced silicon-transparent conductor interface, such as the solar cell of FIG. 12, according to the methods of this invention. The apparatus of FIG. 14 comprises three systems. The first system 1401 deposits the silicon solar stack on a suitable substrate with a back contact. The solar stack may be formed of a-Si, microcrystalline silicon, or single crystal epitaxial layers, for example. An example of such a system is a PECVD tool, although HWCVD tools and LPCVD tools may also be used. The second system 1402 deposits Ni nanowires on the surface of the silicon solar stack, following the method described above with reference to FIG. 5. The third system 1403 deposits a TCO layer on the silicon stack coated with Ni nanowires. An example of such a system is a sputter deposition tool.

Although the present invention has been described for a solar device as shown in FIG. 12, the concepts of the invention are also applicable to tandem solar cells and cells with other configurations. Furthermore, although the apparatus in FIGS. 13 and 14 has been described for silicon solar cells, the solar stack may be formed of microcrystalline silicon, single crystal silicon, or other materials such as SiGe, CIGS, GaAs, InP and CdTe.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A solar cell comprising:
a solar cell stack; and
a conductive layer attached to the surface of said solar cell stack, said conductive layer including:
a multiplicity of magnetic nanostructures in a plane, said multiplicity of magnetic nanostructures being aligned in strings, said strings being roughly parallel to each other and configured to provide a plurality of continuous conductive pathways;
wherein the density of said multiplicity of magnetic nanostructures provides substantial optical transparency of said conductive layer.

2. A solar cell as in claim 1, wherein said multiplicity of magnetic nanostructures are a multiplicity of nanowires, the nanowires being aligned roughly (1) parallel to each other and (2) with the long axes of the nanowires in the plane of said conductive layer.

3. A solar cell as in claim 2, wherein said multiplicity of nanowires comprise nickel and said solar cell stack is a silicon solar cell stack.

4. A solar cell as in claim 1, wherein at least one of said multiplicity of magnetic nanostructures comprises:
a non-magnetic conductive center; and
a magnetic coating.

5. A solar cell as in claim 4, wherein said non-magnetic center is silver, said magnetic coating is nickel and said solar cell stack is a silicon solar cell stack.

6. A solar cell as in claim 1, further comprising:
a continuous conductive film, said continuous conductive film being substantially optically transparent;
wherein said multiplicity of magnetic nanostructures are between said continuous conductive film and said solar cell stack and electrically connected to both said continuous conductive film and said solar cell stack.

7. A solar cell as in claim 6, wherein said continuous conductive film comprises a transparent conductive oxide.

8. A solar cell as in claim 1, wherein said multiplicity of magnetic nanostructures are chosen from the group consisting of nanoparticles, nanowires and compound nanowires.

9. A solar cell as in claim 1, wherein the workfunction of said multiplicity of magnetic nanostructures is matched to the workfunction of said solar cell stack.

10. A solar cell as in claim 1, wherein said solar cell stack comprises a silicon material chosen from the group consisting of amorphous silicon, microcrystalline silicon and single crystal silicon.

11. A method of forming a solar cell, comprising:
providing an optically transparent substrate;
providing a multiplicity of magnetic nanostructures;
depositing a multiplicity of magnetic nanostructures on said optically transparent substrate;
applying a magnetic field to form said multiplicity of magnetic nanostructures into a plurality of conductive pathways parallel to the surface of said optically transparent substrate; and
depositing semiconductor material on said optically transparent substrate coated with said multiplicity of magnetic nanostructures, said semiconductor material fowling a solar cell stack;
wherein said plurality of conductive pathways is substantially optically transparent.

12. A method as in claim 11, wherein said optically transparent substrate comprises a continuous conductive film at the surface of said optically transparent substrate.

13. A method as in claim 11, further comprising annealing said plurality of conductive pathways on the surface of said optically transparent substrate before said depositing semiconductor material.

14. A method as in claim 11, further comprising fusing together said plurality of conductive pathways on the surface of said optically transparent substrate before said depositing semiconductor material.

15. A method as in claim 11, further comprising pressing said plurality of conductive pathways on the surface of said optically transparent substrate before said depositing semiconductor material.

16. A method as in claim 11, further comprising depositing a back contact on said solar cell stack.

17. An apparatus for forming a solar cell, comprising:
a first system to deposit a multiplicity of magnetic nanostructures on an optically transparent substrate, and apply a magnetic field to form said multiplicity of magnetic nanostructures into a plurality of conductive pathways parallel to the surface of said optically transparent substrate;
a second system to deposit semiconductor material on said optically transparent substrate coated with said multiplicity of magnetic nanostructures, said semiconductor material forming a solar cell stack; and
a third system to deposit a back contact on said solar cell stack;
wherein said plurality of conductive pathways is substantially optically transparent.

18. An apparatus as in claim 17, wherein said first system further includes a tool for annealing said plurality of conductive pathways on the surface of said optically transparent substrate.

19. An apparatus as in claim 17, wherein said first system further includes a tool for fusing together said plurality of conductive pathways on the surface of said optically transparent substrate before said depositing semiconductor material

20. An apparatus as in claim 17, wherein said first system further includes a tool for pressing said plurality of conductive pathways on the surface of said optically transparent substrate before said depositing semiconductor material.
